(19) United States
(12) Patent Application Publication
(10) Pub. No.: US 2011/0298455 A1
(43) Pub. Date: Dec. 8, 2011

(54) Integrated Microfluidic Sensor System with Magnetostrictive Resonators

(75) Inventors: Cai Liang, Thuwal (SA); Jurgen Kosel, Thuwal (SA); Chinthaka Gooneratne, Thuwal (SA)

(73) Assignee: King Abdullah University of Science and Technology, Thuwal (SA)

(21) Appl. No.: 13/100,970

(22) Filed: May 4, 2011

Related U.S. Application Data
(60) Provisional application No. 61/331,263, filed on May 4, 2010.

(51) Int. Cl. G01R 33/02; G01D 7/02

(52) U.S. Cl. 324/252; 324/244; 73/866.3

(57) ABSTRACT

The present embodiments describe a method that integrates a magnetostrictive sensor with driving and detecting elements into a microfluidic chip to detect a chemical, biochemical or biomedical species. These embodiments may also measure the properties of a fluid such as viscosity, pH values. The whole system can be referred to lab-on-a-chip (LOC) or micro-total-analysis-systems (μTAS). In particular, this present embodiments include three units, including a microfluidics unit, a magnetostrictive sensor, and driving/detecting elements. An analyzer may also be provided to analyze an electrical signal associated with a feature of a target specimen.

### CROSS-REFERENCE TO RELATED APPLICATIONS

This application claims priority to U.S. Provisional Application No. 61/331,263 filed May 4, 2010. The entire text of the above-referenced disclosure is specifically incorporated herein by reference without disclaimer.

### BACKGROUND OF THE INVENTION

1. Field of the Invention

This invention relates to fluid analysis systems and more particularly relates to an integrated microfluidic sensor system with magnetostrictive resonators.

2. Description of the Related Art

Currently, there are several techniques used to detect chemical, biochemical or biomedical species such as the conventional chromatography and mass spectrometry, Polymerase Chain Reaction (PCR) and others. Mass spectrometry is used for determining masses of particles, for determining the elemental composition of a sample or molecule, and for elucidating the chemical structures of molecules, such as peptides and other chemical compounds. Other testing methods include the use of Quartz crystal microbalance (QCM) sensors and Magnetostrictive sensors. Unfortunately each of the testing methods and systems of the prior art have drawbacks that limit their efficiency and increase the cost of testing.

For example, PCR involves amplifying a single or a few copies of a piece of DNA across several orders of magnitude, generating thousands to millions of copies of a particular DNA sequence. PCR is now a common technique used in medical and biological research labs for a variety of applications, including DNA cloning for sequencing, DNA-based phylogeny, functional analysis of genes, the diagnosis of hereditary diseases, the identification of genetic fingerprints, and the detection and diagnosis of infectious diseases. PCR methods rely on thermal cycling for enzymatic replication of the DNA. One problem with common PCR methods is that the systems typically require a heating element. The heating elements are typically separate components, and therefore, the volume of samples that can be processed is typically restricted by the size or capacity of the heater.

QCM and micro cantilever based mass sensors have also been used to measure or detect the species that interact with the sensors. For example, a QCM sensor may detect a species as a result of the mass change. But typical QCM sensors typically require full immersion in an analyte solution, and therefore are not as useful for testing small samples as other methods. Vibration-based sensors such as cantilevers have been used to detect chemicals or biological species for many years. These sensors may be fashioned into cantilevers and may operate in the transverse mode, which means that the vibration is an out-of-plane motion. The application principle of such sensors in detecting chemicals or biological molecules may be based on the change of the resonance frequency of the cantilevers as a result of mass loading on the sensors. The sensitivity of these vibration-based sensors may be proportional to the resonant frequency of the cantilever. Unfortunately, cantilevers vibrating in transverse mode may have lower resonant frequencies than is desired for many applications.

Magnetostrictive sensors have previously been used to detect the presence of chemicals or biochemical species in an analyte. In previous applications, the magnetostrictive sensors have been large in size and exhibited low sensitivity. Additionally, the driving and detecting elements are typically on a macro scale. A macro scale fluidic cell and apparatus, which requires large volume samples, have been used to facilitate targeted species attaching to sensors. In addition, the detecting signal of macro scale detecting elements has been weak and required a very skillful engineer to process all the analysis steps. As a result, it is not cost effective and the results are often inaccurate.

Each of the sensing methods described above have additional drawbacks. For example, these sensing methods typically require the use of external components and test setups can often be complex and costly. Additionally, it may not be practical to use certain of these methods for processing of a large number of samples simultaneously.

### SUMMARY OF THE INVENTION

The present embodiments describe systems that integrate a magnetostrictive sensor with driving and detecting elements into microfluidic chips to detect a chemical, biochemical or biomedical species. These embodiments may also measure the properties of a fluid such as viscosity or pH values. In some embodiments, these systems may be referred to as lab-on-a-chip (LOC) or micro-total-analysis-systems (μTAS). In particular, the present embodiments include a microfluidics unit, a magnetostrictive sensor, and driving/detecting elements. An analyzer may also be provided to analyze an electrical signal associated with a feature of a target specimen.

An apparatus comprising a microfluidic system is presented. In one embodiment, the apparatus includes a microfluidic device configured to prepare a target specimen for interaction with a magnetic sensor. The apparatus may also include a magnetic sensor coupled to the microfluidic device, the magnetic sensor configured to detect a feature of the target specimen. Additionally, the apparatus may include a driving element coupled to the magnetic sensor, the driving element configured to generate a driving signal for activating the magnetic sensor. Also, the apparatus may include a sensing element coupled to the magnetic sensor, the sensing element configured to detect a response signal from the magnetic sensor in response to the driving signal, the response signal comprising information associated with the feature of the target specimen. In certain embodiments, the driving element and the sensing element may be integrated into a single component of the apparatus. In a further embodiment, the magnetic sensor is a magnetostrictive sensor.

In a particular embodiment, the driving element and the sensing element are integrated together. The driving element and the sensing element may include an inductive element. For example, the inductive element may be a coil.

A system is also presented. In one embodiment, the system includes a μTAS and an analyzer coupled to the microfluidic system. In one embodiment, the microfluidic system may include a microfluidic device configured to prepare a target specimen for interaction with a magnetic sensor. The microfluidic system may also include a magnetic sensor coupled to the microfluidic device, the magnetic sensor configured to detect a feature of the target specimen. Additionally, the microfluidic system may include a driving element coupled to the magnetic sensor, the driving element configured to generate a driving signal for activating the magnetic sensor, and a sensing element coupled to the magnetic sensor, the sensing element configured to detect a response signal from the magnetic sensor in response to the driving signal, the response signal comprising information associated with the feature of the target specimen. An external magnetic field may be applied to magnetize the sensor. The magnetic field can be generated from a permanent magnet or a coil with DC current. The analyzer may analyze the response signal to generate a quantitative representation of the feature of the target specimen. In a further embodiment, the system may also include a fluid source configured to provide a target specimen to the microfluidic device.

In another embodiment, the analyzer may identify a resonant frequency associated with the feature of the target specimen. Further, the analyzer may measure a first resonant frequency of the response signal before the micro-volume of the target specimen is introduced to the magnetic sensor and a second resonant frequency of the response signal after the micro-volume of the target specimen is introduced to the magnetic sensor. Multiple measurement of frequency may be needed according to the interaction between the target species and the sensor.

In still a further embodiment, the system may include a display device coupled to the analyzer for displaying quantitative representation of the feature of the target specimen. In one embodiment, the system may also include a housing. The microfluidic system and the analyzer may both be disposed within the housing. In a further embodiment, the microfluidic system and the analyzer are integrated into a single chip package. Alternatively, the microfluidic system may be disposed within the housing, and the analyzer may be disposed external to the housing.

Methods are also presented. In one embodiment, the method includes preparing a target specimen, using a microfluidic device, for interaction with a magnetic sensor. Also, the method may include detecting a feature of the target specimen with a magnetic sensor. Additionally, the method may include generating a driving signal for activating the magnetic sensor, and detecting a response signal from the magnetic sensor in response to the driving signal, the response signal comprising information associated with the feature of the target specimen. In a further embodiment, the method may include providing a target specimen to the microfluidic device.

Another embodiment of a method is also provided. In this embodiment, the method may include preparing a micro-volume of a target specimen and introducing the micro-volume of the target specimen to a magnetic sensor. This method may also include activating the magnetic sensor with a driving signal and detecting a response signal from the magnetic sensor in response to the driving signal, the response signal comprising information associated with the feature of the target specimen.

In one embodiment, the information associated with the feature of the target specimen comprises a resonant frequency associated with the feature of the target specimen. In a particular embodiment, detecting the response signal from the magnetic sensor includes measuring a first resonant frequency of the response signal before the micro-volume of the target specimen is introduced to the magnetic sensor and a second resonant frequency of the response signal after the micro-volume of the target specimen is introduced to the magnetic sensor. Multiple measurement of frequency may be needed according to the interaction between the target species and the sensor.

In certain embodiments, the microscale magnetostrictive sensors may be fabricated in particle form. The micro scale driving and sensing elements may comprise a coil. The coil may be fabricated in, for example, silicon or glass wafer. The microscale magnetostrictive sensor is introduced into the chip whenever the interaction of target species and sensors takes place. The electrical signals may also be detected on the chip. Thus, the present embodiments may comprise an integrated microfluidic system. An additional benefit of the present embodiments is the ability to take an effective measurement with a very small sample volume.

In the current embodiments, the apparatus may be more sensitive. Additionally, the apparatus and system may be easier and cheaper to mass fabricate. Another benefit of the present embodiments is the ability to implement target analysis in very small scale environments. Such embodiments may, for example, be implemented in portable or transportable feature detection systems.

The term “coupled” is defined as connected, although not necessarily directly, and not necessarily mechanically.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1A is a schematic block diagram illustrating one embodiment of a system for analyzing fluids;

FIG. 1B is a schematic block diagram illustrating another embodiment of a system for analyzing fluids;

FIG. 2A is a schematic block diagram illustrating one embodiment of a μTAS;

FIG. 2B is a schematic diagram illustrating one embodiment of μTAS integration;

FIG. 3 is a schematic block diagram of one embodiment of an analyzer as described in FIG. 1B;

FIG. 4 is a perspective view diagram of one embodiment of a microfluidic system;

FIG. 5 is a schematic flowchart diagram illustrating one embodiment of a method for analyzing fluids;

FIG. 6 is a schematic flowchart diagram illustrating another embodiment of a method for analyzing fluids;

FIG. 7 is a semiconductor processing flow diagram illustrating one embodiment of a method for manufacturing a magnetostrictive sensor;

FIG. 8 is a logical layout diagram illustrating an overview of the device consisting of Microfluidics channels, chambers, inlet, outlet, driving and detecting elements.

FIG. 9 is a graphical plot illustrating a frequency response of one embodiment of a magnetostrictive sensor.

### DETAILED DESCRIPTION

Various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

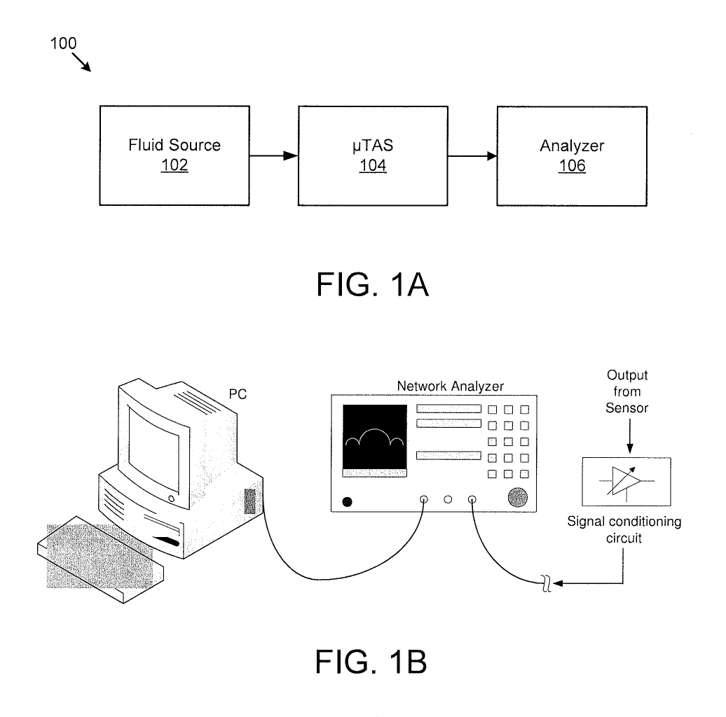

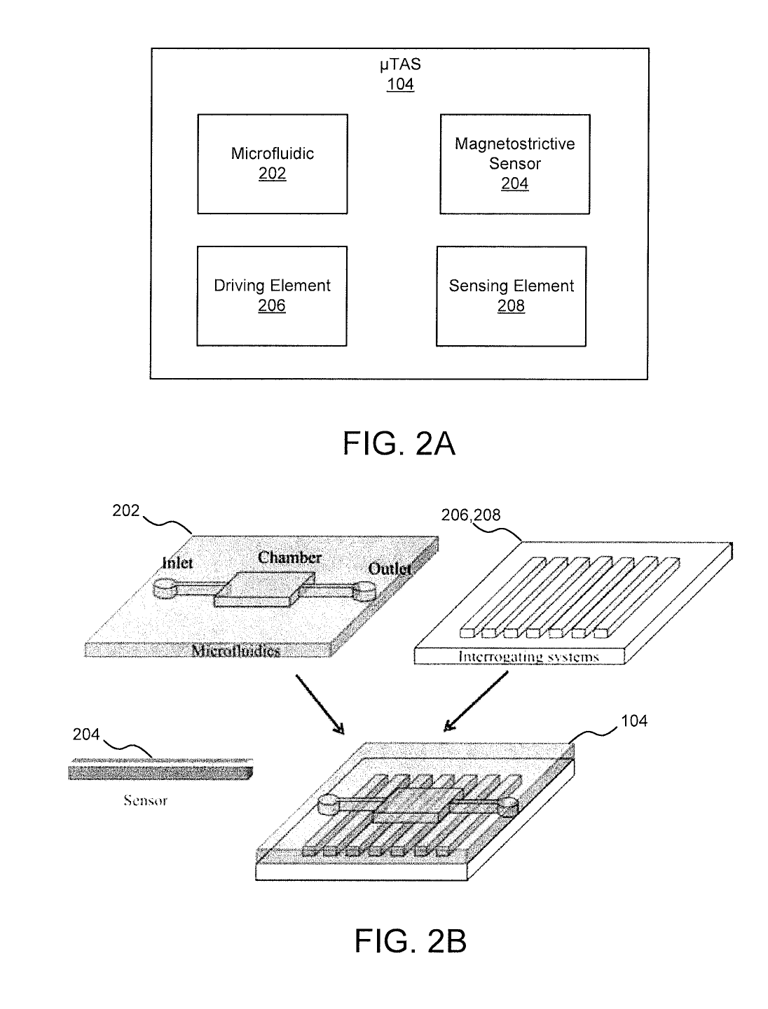

FIG. 1 illustrates one embodiment of a system 100 for microfluidics. In one embodiment, the system 100 includes a fluid source 102, a microfluidic system 104, and an analyzer 106 coupled to the microfluidic system 104. Embodiments of the microfluidic system 104 are described in further detail below with respect to FIG. 2A. The fluid source 102 may provide a target specimen to the microfluidic system 104. The analyzer 106 may analyze a response signal provided by the microfluidic system 104 to generate a quantitative representation of the feature of a target specimen provided by the fluid source 102.

In another embodiment, the analyzer 106 may identify a resonant frequency associated with the feature of the target specimen. Further, the analyzer 106 may measure a first resonant frequency of the response signal before the micro-volume of the target specimen is introduced to the magnetic sensor 204 and a second resonant frequency of the response signal after the micro-volume of the target specimen is introduced to the magnetic sensor 204. A microscale magnetostrictive sensor is introduced into the chip whenever the interaction of target species and sensors takes place as described in FIG. 2A. Multiple measurement of frequency may be made according to the interaction between the target species and the sensor. A reference sensor may also be used as to compare to the testing sensor, but it does not have any functional layer on top so that it will not interact with any target species.

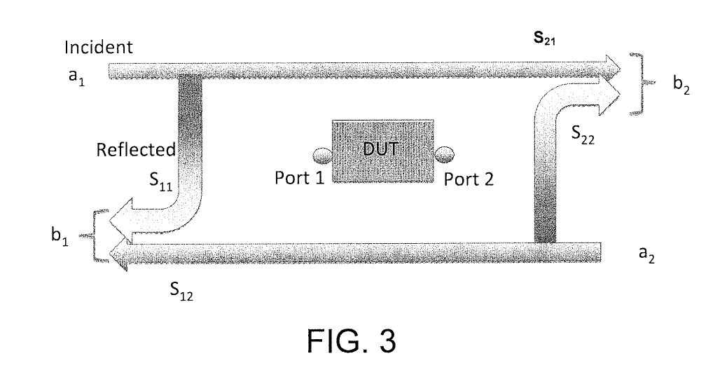

FIG. 1B illustrates a network analyzer adapted to generate a modulating signal to a driving element and a sensing element to drive sensors to vibrate. As the sensors vibrate, the magnetization of the magnetostrictive sensor changes causing changing magnetic flux interacting with the driving element and sensing element to produce an electrical signal. When the frequency of the modulating signal reaches to the sensor's resonant frequency, the oscillation of the sensor peaks; therefore, the magnetic flux may reach a peak change value, hence the largest additional electrical signal is produced in the driving/detecting elements, as a result, the network reflected power will change. The network analyzer may analyze such signal in term of the impedance; the output of the signal can be the resonant frequency of the magnetostrictive sensor. Any change of the sensor's condition, for example, the mass loading on the sensor's surface, will change the resonant frequency of the sensor. This can be utilized to detect and quantify the targeted species in the fluid. The network analyzer is a piece of commercially available equipment such HP/Agilent analyzer. Further embodiments of analyzing the electrical signal from the driving element and/or the sensing element are explained in FIG. 3. The return loss of the Device Under Test (DUT) is measured by S-parameter (S₁₁) of a two-port device. In this case, the port two is terminated, so signal of only the reflected power from the DUT is analyzed, which is directly related to the sensor's response.

FIG. 2A illustrates one embodiment of a microfluidic system 104. In the depicted embodiment, the microfluidic system 104 includes a microfluidic 202 configured to prepare a target specimen for interaction with a magnetic sensor 204. The microfluidic 202 may be fabricated from polydimethysiloxane (PDMS), silicon (Si) or glass will serve as a complex reaction unit so that the target species (e.g., a chemical, a biochemical, a biomedical molecule, or a fluid), will be prepared and interact with the magnetic sensor 204. In a further embodiment, multiple magnetic sensors 204 may be used in the microfluidic system 104. This microfluidic 202 may include multiple inlets/outlets, control valves, channels, mixers, heaters, separation, and reaction chambers.

In one embodiment, the microfluidic 202 may be fabricated in such a way that the interaction of the sensor and the sample solution occurs in one chamber and the interrogation of the sensor signal processes in another chamber. For example, in one embodiment the microfluidic 202 may be fabricated on a PMMA polymer substrate using a CO₂ laser cutting system (Universal Laser Systems). In one embodiment, the height of chamber and channel may be about 100 μm. In a further embodiment, the size of the chamber may be varied to accommodate the interrogating elements. In one embodiment, the diameter of inlet and outlet may be 1.0 mm. In order to fabricate a microfluidic system with less surface roughness and undercut, the Universal Laser System may be powered at 5 W, and the cutter may move at a speed of 2 cm/s for fabrication of the microfluidics. One of ordinary skill in the art will recognize a variety of alternative chamber formation methods that are suitable for use with the present embodiments.

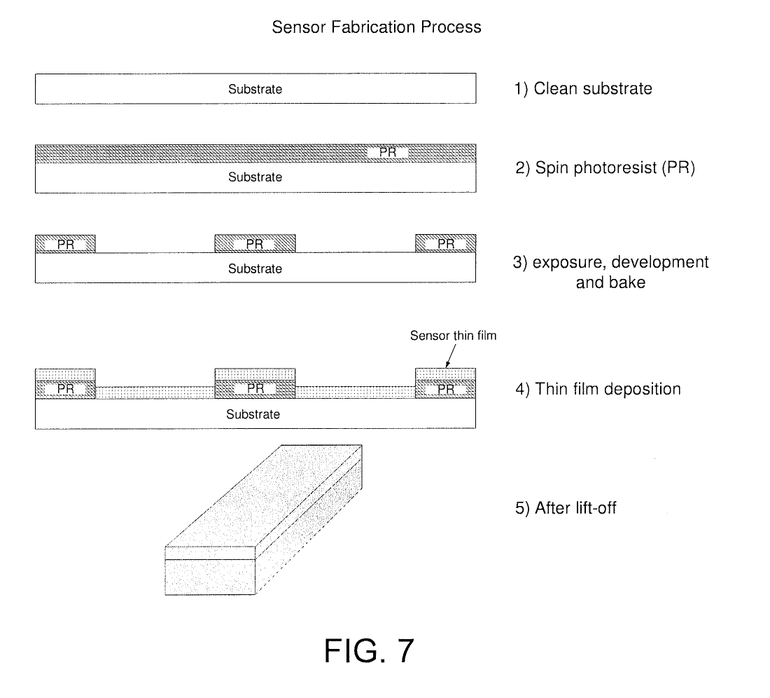

The microfluidic system 104 may also include a magnetic sensor 204 coupled to the microfluidic 202, the magnetic sensor 204 may be configured to detect a feature of the target specimen like E. coli, Salmonella typhimurium, and Bacillus anthracis spores In a further embodiment, the magnetic sensor 204 is a magnetostrictive sensor. The magnetic sensor 204 may, for example, include a ferromagnetic device that is fabricated by the standard MEMS process (see FIG. 7), or fabricated from bulk materials such as Metglas™ at various sizes. Metglas™ is available from Metglas®, Inc., which is located at 440 Allied Drive, Conway, S.C. 29526. In a particular embodiment, this magnetic sensor 204 may vibrate under modulated magnetic field, which resonant frequency is detected by driving and detecting element as described below. Once there is a change in mass of the magnetic sensor 204, or change in the interface between the sensor surface and the surrounding, the resonant frequency of the magnetic sensor 204 will change. Based on this principle, the sensor 204 can be used to detect target species, such as heavy or toxic metals (Ag, Pb) in earth water, E. Coli in food or drinking water. In addition, such magnetic sensors 204 may be used for measuring the viscosity of a liquid, for example, oil.

Magnetic sensors 204 implemented as a magnetostrictive freestanding beam that is vibrating in longitudinal mode with an in-plane motion, have great advantages over the conventional transverse mode systems. This is not only due to the higher frequency but also due to the easier principle of operation. Additionally, sensors made of magnetostrictive materials can be interrogated wirelessly, in other words, there are no electrical wirings attached to the sensors. To further improve the sensitivity of such sensors, reduction of the sensors' size may increase sensitivity because the sensitivity is proportional to the reciprocal of the sensor's mass and length. In addition, sensors that are fabricated in microscale show higher Q values, and can be integrated into microsystems, which results in further advantages like less analyte consumption in the case of biomedical applications.

In one embodiment, freestanding beams may be fabricated with sizes of 500 μm×100 μm and 100 μm×20 μm with a thickness of 2.5 μm using a lift-off process. One of ordinary skill in the art will recognize, however, that alternative dimensions and processes may be used. Magnetostrictive thin films may be deposited, for example, at a pressure of 7 mTorr by co-sputtering of (Iron-Nickel) Fe—Ni (50/50), (Molybdenum) Mo and (Boron) B targets at power of 200 W, 25 W and 100 W, respectively, to fabricate Fe—NIMo—B thin film materials.

In one embodiment, the magnetic sensor 204 is a microscale magnetostrictive sensors that can be used for, inter alia, chemicals and biological species detection. In order to achieve the similar properties as bulk scale Metglas™ 2826 MB strip, nickel (Ni) and iron (Fe) magnetic materials may be co-sputtered with the Mo and B to fabricate free standing beams which form the sensors platform. The resonant frequency of the sensors may be measured by using a uniquely designed detection element. SEM, XRD, XPS, AFM/MFM and VSM may be used to characterize the sensors' material that directly links to their performance.

The present embodiments may be particularly useful for measuring features of an analyte. An analyte is a liquid solution containing substances that are the interest of analysis. For example, the present embodiments may measure a feature of an analyte. In such an embodiment, the analyte as a whole is analyzed. If, however, the feature to be analyzed is the presence of any individual chemicals (e.g., Pb), or to identify a biochemical species (e.g., E. Coli), then those individuals elements or substances in the analyte may be specifically targeted.

Additionally, the microfluidic system 104 may include a driving element 206 coupled to the magnetic sensor 204, the driving element 206 configured to generate a driving signal for activating the magnetic sensor 204. The driving elements 206 may be the component to generate the actuating signal to drive the sensor to its resonant vibration using a/c or a/c+DC source.

Also, the microfluidic system 104 may include a sensing element 208 coupled to the magnetic sensor 204, the sensing element 208 configured to detect a response signal from the magnetic sensor 204 generated in response to the driving signal, the response signal comprising information associated with the feature of the target specimen.

In a particular embodiment, the driving element 206 and the sensing element 208 may be integrated together. The driving element 206 and the sensing element 208 may include an inductive element. For example, the inductive element may be a coil. The coil may be used to generate the magnetic field that used to drive the magnetic sensor 204. In one embodiment, the driving element 206 and the sensing element 208 may share a common inductive element. Alternatively, the driving element 206 and the sensing element 208 may include separate coils.

The driving element 206 may comprise structures of lines-spaces with a pitch of 5-3 μm or 4-3 μm. Response signals may include an alternating current (A/C) signal for driving the magnetic sensor 204, and a responsive signal used to detect the interaction signal between the magnetic sensor 204 and itself due to the magnetic flux change while the sensor is vibrating. This driving and detecting element may be fabricated on either Si or glass wafer via microfabrication process. In a particular embodiment, the elements 206, 208 may be connected to the analyzer 106 via wire bond on the bond pads.

In one embodiment, the micro-scale coil is an “interdigital” structure. Alternatively, the micro-scale coil may be an “inductive” structure. The lines-spaces for “interdigital” and “inductive” structures are 5-3 μm and 4-3 μm, respectively. In one embodiment, a 100 mm Si wafer (100) with 100 nm SiO₂ may be provided as a substrate. A 500 nm thick Au or Al metal may be deposited on the substrate to form the coils. AZ3027 photo resist (PR) may be used for patterning the features. One of ordinary skill in the art will recognize a variety of alternative patterning methods. C-type Parylene may be provided as a passivation layer. In one embodiment, the C-type Parylene may have a thickness of 1.2 μm. The Parylene may be deposited using a thermal evaporation system. In one example, the thermal evaporation system may operate at a temperature of around 690° C., and a pressure of around 15 Torr. The Parylene may then be etched. For example, the etch process may use O₂ plasma for 29 minutes at a temperature of 100° C. and a pressure of 500 mTorr. The O₂ flow rate may be about 100 SCCM and Ar flow rate of about 14 SCCM to open connection pads.

In one embodiment, after the driving element 206, the sensing element 208, and microfluidics 202 are fabricated, they may be aligned and packaged together using super glue to form one integrated device for testing. Alternative embodiments may incorporate other adhesives, such as epoxy. Still further embodiments may include alternative methods for affixing the elements to the microfluidic 202.

FIG. 2B further illustrates one embodiment of how the microfluidics 202, the magnetic sensors 204, the driving element 206, and the sensing element 208 may be integrated into a microTAS 104. One of ordinary skill in the art will recognize alternative configurations that are suitable for use with the present embodiments.

FIG. 3 illustrates one embodiment of an analyzer 106 that may be adapted for use with the system described in FIG. 1B. In one embodiment, the analyzer 106 may be external to the microfluidic system 104. Alternatively, the analyzer 106 may be integrated into a single device, or on a single chip, with the microfluidic system 104. For example, the analyzer may be a network analyzer as illustrated in FIG. 1B. Alternatively, the analyzer 106 may be electronic chip configured to perform readout of the sensor elements. In such an embodiment, the analyzer 106 may be integrated in the microTAS 104, or packaged in a single unit with the microTAS 104. For example, in one embodiment, the analyzer 106 and the microTAS 104 may be integrated into a single handheld device.

In the current embodiments, the microfluidic system 104 may be more sensitive than prior art solutions. Additionally, the microfluidic system 104 and system 100 may be easier and cheaper to mass fabricate than prior solutions. Another benefit of the present embodiments is the ability to implement target analysis in very small scale environments. Such embodiments may, for example, be implemented in portable or transportable feature detection systems.

In certain embodiments, the microscale magnetic sensors 204 may be fabricated in particle form. For example, the magnetic sensors 204 may include a freestanding microscale beam, which may be referred to a particle because of its size. The micro scale driving and sensing elements 208 may comprise a coil. The coil may be fabricated in silicon or glass wafer and integrated into a microfluidics chip. The electrical signals may also be detected on the chip. Thus, the present embodiments may comprise a microfluidic system 104. An additional benefit of the present embodiments is the ability to take an effective measurement with a very small sample volume.

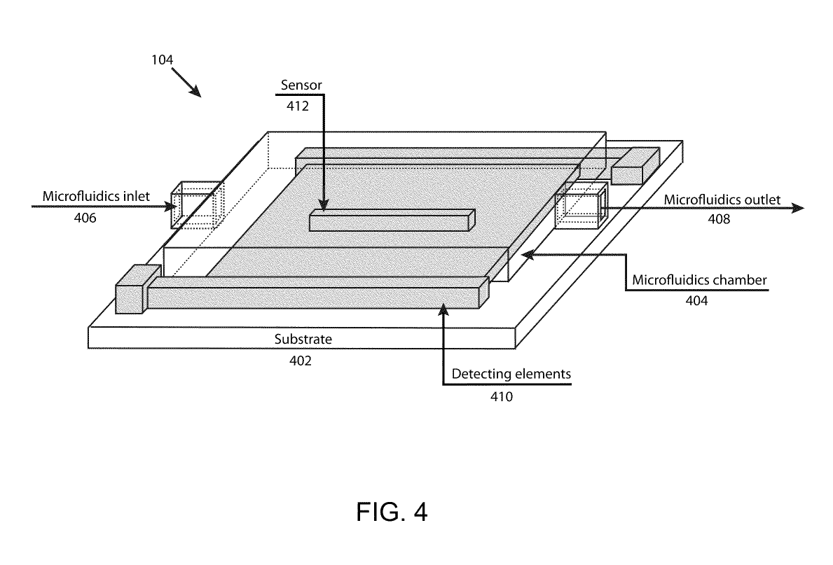

FIG. 4 illustrates another embodiment of a microfluidic system 104. In the depicted embodiment, the microsystem 104 includes a substrate 402. The microsystem may also include a microfluidics chamber 404 having an inlet 406 and an outlet 408. The microsystem 104 may include one or more detecting elements 410 and sensors 412 as illustrated.

The sensor 412 may be made of magnetostrictive materials and fabricated via standard microfabrication process. In one embodiment, the sensor 412 may be a freestanding beam coated with gold (Au) on one side. This may be used for immobilization of antibody, or phage, or the likes, that is to be as a receptor of the targeted analyte. The chemical or biological species loading/bonding processes may be carried in the microfluidics chamber 404. The system may include may include many microfluidics chambers 404 and detecting elements 410, and other components, which are not shown, but which one of ordinary skill in the art may recognize as suitable for use in the system. For example, some chambers may include heaters for processes such as PCR for DNA for example. In such an example, the heaters may be fabricated on the same chip as the microfluidics chambers 404. In an alternative embodiment, the heaters may be separated from the microfluidics chambers 404. The resonant frequency of the sensor 412 before and after each bonding step may be detected using the detecting elements 410. Multiple measurement of frequency may be made according to the interaction between the target species and the sensor. The resonant frequency change may be convert into the mass load on the sensor 412, which may describe the concentration of the targeted analyte.

The schematic flow chart diagrams that follow are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

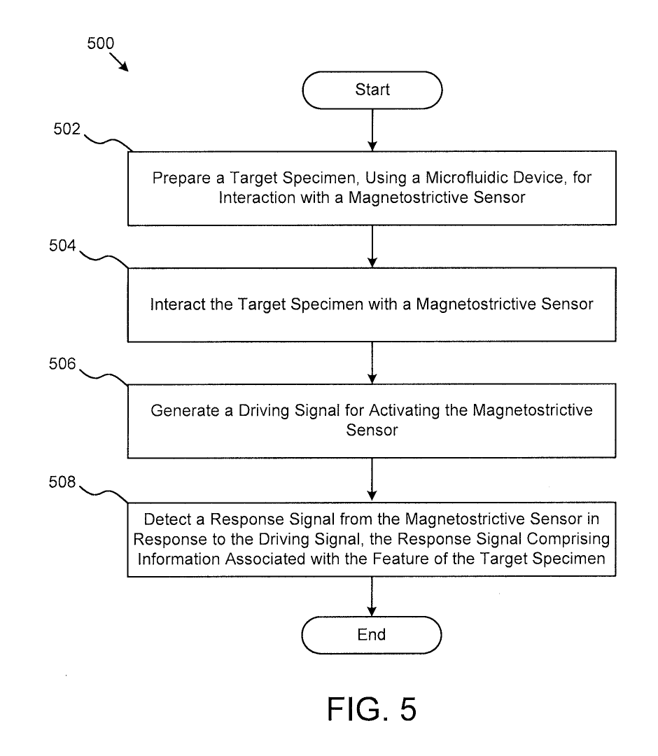

FIG. 5 illustrates one embodiment of a method 500 for analyzing microfluidics. In one embodiment, the method 500 includes preparing 502 a target specimen, using a microfluidic 202, for interaction with a magnetic sensor 204. Also, the method 500 may include interacting 504 a feature of the target specimen with a magnetic sensor 204. Additionally, the method 500 may include generating 506 a driving signal for activating the magnetic sensor 204, and detecting 508 a response signal from the magnetic sensor 204 in response to the driving signal, the response signal comprising information associated with the feature of the target specimen. For example, a combine driving element 206/sensing element 208 may be used to both generate 506 the driving signal and detect 508 the response signal. In a further embodiment, the method 400 may include providing a target specimen to the microfluidic 202.

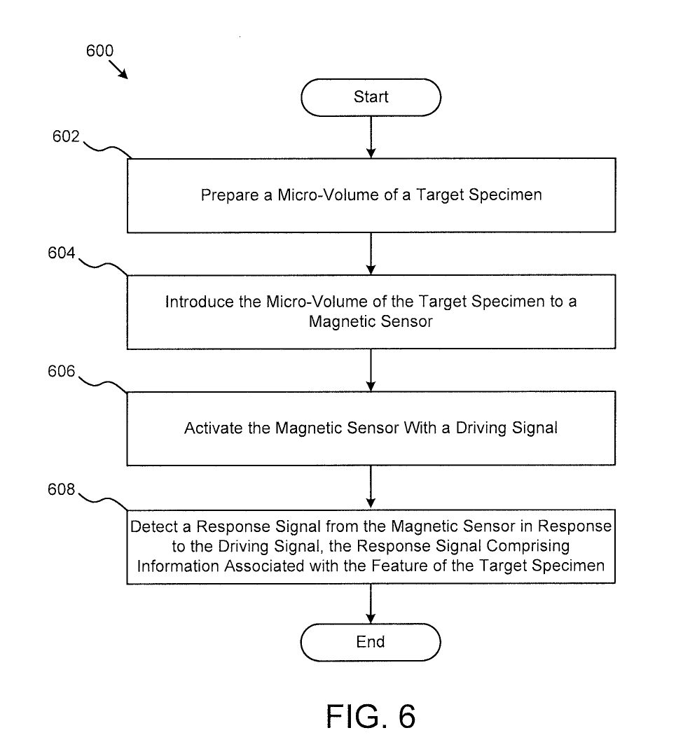

FIG. 6 illustrates another embodiment of a method 600 for analyzing microfluidics. In this embodiment, the method 600 may include preparing 602 a micro-volume of a target specimen and introducing 604 the micro-volume of the target specimen to a magnetic sensor 204. This method 600 may also include activating 606 the magnetic sensor 204 with an driving signal and detecting 608 a response signal from the magnetic sensor 204 in response to the driving signal, the response signal comprising information associated with the feature of the target specimen.

FIG. 7 illustrates one embodiment of a process flow for manufacturing a sensor. In one embodiment, the method includes cleaning a substrate. The method may also include providing a layer of photoresist on the surface of the substrate and patterning the photoresist. The photoresist may then be exposed to, e.g., utlraviolet radiation, and baked to harden the photoresist mask. Then, thin film may be applied to the surface of the substrate and the photoresist. In one embodiment, the thin film may include a material suitable for forming a magnetostrictive sensor, e.g., FeNiMoB or Metglas™. In various embodiments, the thin film may be deposited by a physical sputtering process, PVD, or the like. Finally, after a lift-off process is performed, the patterned magnetostrictive sensor may be released from the wafer and collected, cleaned and ready for use.

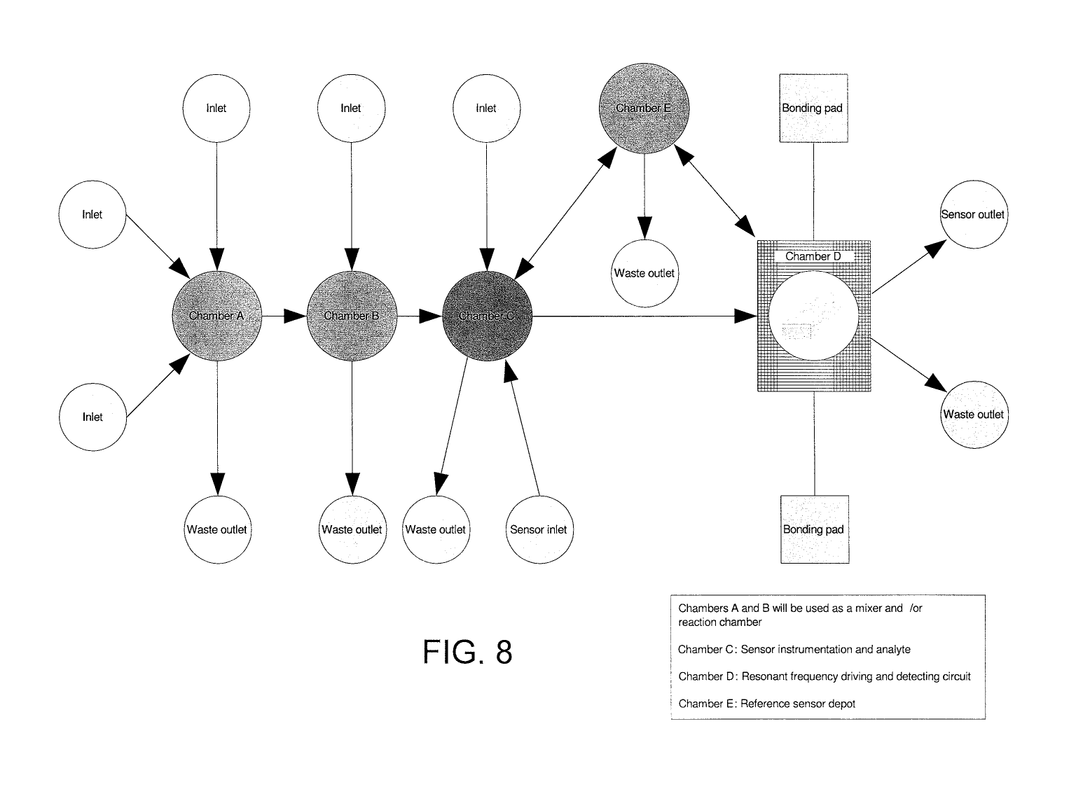

FIG. 8 illustrates one embodiment of a system for microfluids. As described in this Figure, Chamber A and Chamber B may be used for mixing and preparing a solution for interaction with a magnetic sensor. In Chamber C, the sensor may be introduced for interaction with the solution. For example, the sensor may be introduced through the sensor inlet. The sensor may then be moved to Chamber D for driving and detecting the resonant frequency of the sensor before and after having bonded analyte. Similarly, Chamber E may use to store a reference sensor. The reference may not have the functional layer for the analyte bonded to the surface of the sensor. Thus, the reference sensor may provide a reference signal. In such an embodiment, the reference sensor may be prepared in Chamber E and then moved to Chamber D to provide a reference signal. Whenever the testing sensor is transferred to the chamber D, the reference sensors will be transferred to chamber E. The arrow/line represents the microfluidic channel and movement direction.

In one embodiment, the information associated with the feature of the target specimen comprises a resonant frequency associated with the feature of the target specimen. In a particular embodiment, detecting the response signal from the magnetic sensor 204 includes measuring a first resonant frequency of the response signal before the micro-volume of the target specimen is introduced to the magnetic sensor 204 and a second resonant frequency of the response signal after the micro-volume of the target specimen is introduced to the magnetic sensor 204. Multiple measurement of frequency may be needed according to the interaction between the target species and the sensor.

Microfluidics 202, the driving element 206 and the detecting element 208 may be fabricated separately, and then bonded or packaged together in wafer level. Finally, dicing them to individual chip. The magnetic sensor 204 may be fabricated by itself and used in the chips. In alternative methods, these components may be fabricated on a single substrate using a common process.

When the present embodiments are used to measure a physical property of an analyte, for example, the viscosity of a blood or a liquid, the analyte may be directly introduced to the device 104. The resonant frequency may be measured by an analyzer 106 before and during the analyte introduction.

When it is applied to determine the chemicals, for example, lead or mercury, a chemical absorption coating on the magnetic sensor 204 surface may be prior to introducing the sensors during or after the sensors fabrication process in the system 100.

To determine the biological/biomedical species in an analyte, this magnetic sensor 204 may be coated with a biocompatible layer such as Au on the sensors surface in the fabrication process. A selective receptor layer, such as antibody or phage, may be immobilized first so that the target species/substance in the analyte can be selectively bonded onto the receptor. The immobilization of receptor and attachment of the target substance steps may be conducted in the microfluidics.

The present embodiments may be used in monitoring environment, food production, storage, and supply chains, water source contamination, oil production, chemical production, clinic analysis, antiterrorism and battlefield (such as explosive vapors).

There are several advantages of using micro scale driving and detecting element 206, 208. For example, the elements 206, 208 may be comparable with the micro scale sensors hence a strong signal to be received. Additionally, it may be easy to be integrated into a micro fluidics. As a result, a microfluidic system 104 is developed and much less sample quantity is required to process the analysis the species. Another advantage is that the microfluidic system 104 may be easily mass produced in a microfabrication line. In general, the present embodiments may be more cost effective and user friendly than previously known methods for analyzing fluids.

The benefits of these embodiments will be greatly reducing the cost as a whole. The traditional techniques for analyzing the chemicals or biological species rely on the chromatography and spectrometry, and PCR, it usually takes hours to days in the lab or clinic. The present embodiments not only can shorten the analysis time, but the device is also portable, can be brought to the field (point-of-care device).

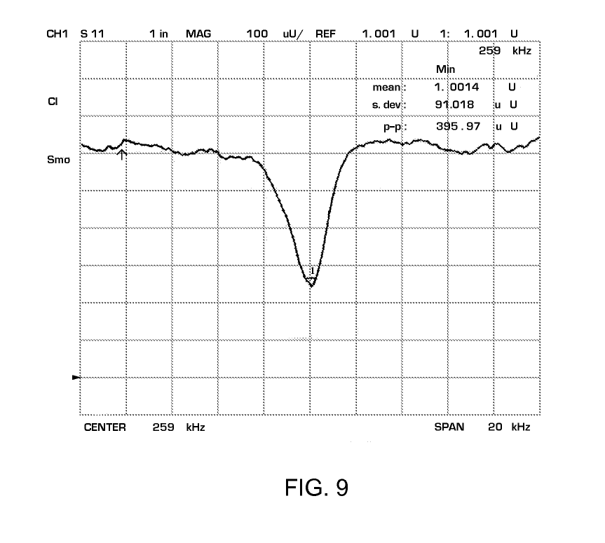

FIG. 9 illustrates a frequency response of one embodiment of a magnetic sensor 204 according to the present embodiments. The peak illustrates corresponds to the resonant frequency of the magnetic sensor 204.

All of the methods disclosed and claimed herein can be made and executed without undue experimentation in light of the present disclosure. While the microfluidic system and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed microfluidic system 104 and components may be eliminated or substituted for the components described herein where the same or similar results would be achieved. All such similar substitutes and modifications apparent to those skilled in the art are deemed to be within the spirit, scope, and concept of the invention as defined by the appended claims.

What is claimed is:

1. An apparatus comprising:
a microfluidic device configured to prepare a target specimen for interaction with a magnetic sensor;
a magnetic sensor coupled to the microfluidic device, the magnetic sensor configured to detect a feature of the target specimen;
a driving element coupled to the magnetic sensor, the driving element configured to generate a driving signal for activating the magnetic sensor; and
a sensing element coupled to the magnetic sensor, the sensing element configured to detect a response signal from the magnetic sensor in response to the driving signal, the response signal comprising information associated with the feature of the target specimen.

2. The apparatus of claim 1, wherein the magnetic sensor comprises a magnetostrictive sensor.

3. The apparatus of claim 1, wherein the driving element and the sensing element are integrated together.

4. The apparatus of claim 3, wherein the driving element and the sensing element comprise an inductive element.

5. The apparatus of claim 4, wherein the inductive element comprises a coil.

6. A system comprising:
a microfluidic system comprising:
a microfluidic device configured to prepare a target specimen for interaction with a magnetic sensor;
a magnetic sensor coupled to the microfluidic device, the magnetic sensor configured to detect a feature of the target specimen;
a driving element coupled to the magnetic sensor, the driving element configured to generate a driving signal for activating the magnetic sensor; and
a sensing element coupled to the magnetic sensor, the sensing element configured to detect a response signal from the magnetic sensor in response to the driving signal, the response signal comprising information associated with the feature of the target specimen; and
an analyzer coupled to the microfluidic system and configured to analyze the response signal to generate a quantitative representation of the feature of the target specimen.

7. The system of claim 6, further comprising a fluid source configured to provide a target specimen to the microfluidic device.

8. The system of claim 7, wherein the analyzer is configured to identify a resonant frequency associated with the feature of the target specimen.

9. The system of claim 8, wherein the analyzer is configured to measure a first resonant frequency of the response signal before the micro-volume of the target specimen is introduced to the magnetic sensor and a second resonant frequency of the response signal after the micro-volume of the target specimen is introduced to the magnetic sensor.

10. The system of claim 6, further comprising a display device coupled to the analyzer for displaying quantitative representation of the feature of the target specimen.

11. The system of claim 6, further comprising a housing.

12. The system of claim 11, wherein the microfluidic system and the analyzer are both disposed within the housing.

13. The system of claim 12, wherein the microfluidic system and the analyzer are integrated into a single chip package.

14. The system of claim 11, where the microfluidic system is disposed within the housing, and the analyzer is disposed external to the housing.

15. A method comprising:
preparing a target specimen, using a microfluidic device, for interaction with a magnetic sensor;
interacting a feature of the target specimen with a magnetic sensor;
generating a driving signal for activating the magnetic sensor; and
detecting a response signal from the magnetic sensor in response to the driving signal, the response signal comprising information associated with the feature of the target specimen.

16. The method of claim 15, further comprising providing a target specimen to the microfluidic device.

17. A method comprising:
preparing a micro-volume of a target specimen;
introducing the micro-volume of the target specimen to a magnetic sensor;
activating the magnetic sensor with an driving signal;
detecting a response signal from the magnetic sensor in response to the driving signal, the response signal comprising information associated with the feature of the target specimen.

18. The method of claim 17, wherein the information associated with the feature of the target specimen comprises a resonant frequency associated with the feature of the target specimen.

19. The method of claim 17, wherein detecting the response signal from the magnetic sensor further comprises measuring a first resonant frequency of the response signal before the micro-volume of the target specimen is introduced to the magnetic sensor and a second resonant frequency of the response signal after the micro-volume of the target specimen is introduced to the magnetic sensor.
